(19) United States
(12) Patent Application Publication
(10) Pub. No.: US 2025/0120191 A1
(43) Pub. Date: Apr. 10, 2025

(54) INCREASING AVALANCHE PROBABILITY IN PHOTODIODES

(71) Applicant: SRI International, Menlo Park, CA (US)

(72) Inventors: Winston K. Chan, Princeton, NJ (US); David John Hill, Lawrenceville, NJ (US)

(21) Appl. No.: 18/836,429

(22) PCT Filed: Dec. 21, 2022
(86) PCT No.: PCT/US2022/082162

§ 371 Date: Aug. 7, 2024

Related U.S. Application Data
(60) Provisional application No. 63/307,894, filed on Feb. 8, 2022.

(51) Int. Cl. H10F 30/225; G01S 7/481; H10F 71/00; H10F 77/124; H10F 77/14

(52) U.S. Cl. CPC H10F 30/2255; G01S 7/4816; H10F 71/1272; H10F 77/1248; H10F 77/147; H10F 77/148

(57) ABSTRACT

An example Geiger mode avalanche photodiode includes a first semiconductor alloy forming a compositionally graded gain region configured to form a conduction band having free electrons, a valence band having free holes, and a bandgap between the valence band and the conduction band that varies in size across the graded gain region; a second semiconductor alloy forming an absorber region; and a semiconductor substrate.

This application claims the benefit of U.S. Provisional Patent Application No. 63/307,894, filed Feb. 8, 2022, the entire contents of which is incorporated herein by reference.

### TECHNICAL FIELD

This disclosure is related to photodiodes.

### BACKGROUND

A photodiode, such as a Geiger mode avalanche photodiode (GmAPD), is a highly sensitive device that can detect the arrival of single photons. It has applications in light detection and ranging (LIDAR), low light level imaging, and chemical and biological detection and analysis. Even though the device may detect single photons, the photon detection efficiency (PDE) of a photodiode, such as a GmAPD, is typically about 30-40%. That is, as many as ⅔ of the photons in an already weak signal of incoming photons may remain undetected.

Currently, PDE is determined by two factors: (1) the quantum efficiency which is the probability that an incoming photon generates an electron-hole pair in the photodiode where either the electron or the hole is amplified by impact ionization, and (2) the probability of avalanche which is the probability that the electron or the hole (depending on which the photodiode may be designed to amplify) is amplified enough to create an avalanche that an external circuit can detect. Current methods of increasing the PDE are (1) increasing the quantum efficiency with well-known methods such as using a thicker absorption layer and adding reflectors to cause the light to make multiple passes through the absorption layer, and (2) increasing the bias to increase the probability of avalanche.

However, increasing the bias higher also increases the dark current generation in the gain region through band-to-band tunneling and field-assisted emission from traps, which cases the increase in PDE to be accompanied by an increase in noise due to the dark current. The bias can therefore be increased only so much before the increase in dark current offsets any improvement in PDE.

### SUMMARY

Described herein are techniques for increasing the PDE of a photodiode, such as a GmAPD, by increasing the avalanche probability with a graded composition semiconductor alloy layer.

In one example, a Geiger mode avalanche photodiode comprises a first semiconductor alloy forming a compositionally graded gain region configured to form a conduction band having free electrons, a valence band having free holes, and a bandgap between the valence band and the conduction band that varies in size across the graded gain region; a second semiconductor alloy forming an absorber region; and a semiconductor substrate.

In one example, a method comprises creating a Geiger mode avalanche photodiode by: forming a semiconductor substrate; forming a first semiconductor alloy to include a compositionally graded gain region configured to form a conduction band having free electrons, a valence band having free holes, and a bandgap between the valence band and the conduction band that varies in size across the graded gain region; and forming a second semiconductor alloy to include an absorber region.

In one examples, a photon detection method comprises receiving, by the Geiger mode avalanche photodiode recited in any of the Geiger mode avalanche photodiode claims, a photon incident to the second semiconductor alloy; generating, by the first semiconductor alloy, a gain by amplifying a current, produced by the photon, across the compositionally graded gain region; and outputting, by the avalanche photodiode, an electrical signal based on the gain.

The details of one or more examples of the techniques of this disclosure are set forth in the accompanying drawings and the description below. Other features, objects, and advantages of the techniques will be apparent from the description and drawings, and from the claims.

### BRIEF DESCRIPTION OF DRAWINGS

FIG. 1A is a partial cross-sectional view of an example of an avalanche photodiode, in accordance with one or more techniques of this disclosure.

FIG. 1B is a partial cross-sectional view of an example of an avalanche photodiode, in accordance with one or more techniques of this disclosure.

FIG. 2A is a conceptual diagram illustrating examples of a bandgap between a conduction band and a valence band of a compositionally graded gain region of a photodiode that is not being electrically biased to conduct electrical current, in accordance with one or more techniques of this disclosure.

FIG. 2B is a conceptual diagram illustrating examples of a bandgap between a conduction band and a valence band of a compositionally graded gain region of a photodiode that is being electrically biased to conduct electrical current, in accordance with one or more techniques of this disclosure.

FIG. 2C is a conceptual diagram illustrating examples of an effect the generation of a quasi-field by a compositionally graded gain region, in accordance with one or more techniques of this disclosure.

FIGS. 3A-3B are conceptual diagrams illustrating examples of a semiconductor alloy forming compositionally graded gain regions, in accordance with one or more techniques of this disclosure.

FIG. 4 is a conceptual diagram illustrating probability of avalanche with respect to gain length, electron-initiated impact ionization rate, and hole-initiated impact ionization rate.

FIG. 5 is a flow diagram illustrating an example technique for creating a photodiode configured to have increased avalanche probability, in accordance with one or more techniques of this disclosure.

FIG. 6 is a conceptual diagram illustrating an example of a first semiconductor alloy forming compositionally graded gain regions, in accordance with one or more techniques of this disclosure.

Like reference characters refer to like elements throughout the figures and description.

### DETAILED DESCRIPTION

Previous efforts to increase PDE have focused on increasing the quantum efficiency or to increase the bias to increase the probability of avalanche while lowering the operating temperature to decrease the concomitant increase in dark current. The quantum efficiency may be increased to only 100% so there can be no further improvement in the PDE once the quantum efficiency is at 100%. Lowering the operating temperature may add to the size, weight, and power requirement of the system.

A linear mode photodiode, such as a linear mode avalanche photodiode, may be operated below its avalanche breakdown voltage for which the photocurrent may be proportional to received signal power. A GmAPD may be operated above a breakdown threshold voltage for which the photocurrent may saturate at any level of received optical power, and where a single electron-hole pair (generated by absorption of a photon or by a thermal fluctuation) may trigger a strong avalanche.

Described herein are techniques for increasing the PDE of an avalanche photodiode, such as a GmAPD, by increasing the avalanche probability with a graded composition semiconductor alloy layer. For example, a photodiode as described herein may be created to include a compositionally graded gain region that adds a quasi-electric field for one carrier and subtracts a quasi-electric field for the other carrier. Because an avalanche probability increases as the difference between the electron-initiated ionization rate and the hole-initiated ionization rate increases, the compositionally graded gain region may increase the probability of avalanche for any given photon and enable the photodiode to detect weaker signals, e.g., lower energy photons.

A bias to increase the PDE may be based on a ratio of the electron-initiated impact ionization rate (α) to the hole-initiated impact ionization rate (β). The two ionization rates are material properties that increase rapidly and monotonically as the local electric field increases. If the α/β ratio is greater than unity, then the photogenerated electrons should be amplified, and increasing the ratio may require a lower voltage to increase the PDE to a target value. Conversely, if α/β is less than unity, then the photogenerated holes should be amplified, and decreasing the ratio may require a lower voltage to increase the PDE to a target value. The target value of PDE may require a lower bias to achieve in either case, so unwanted dark current increase may be less severe.

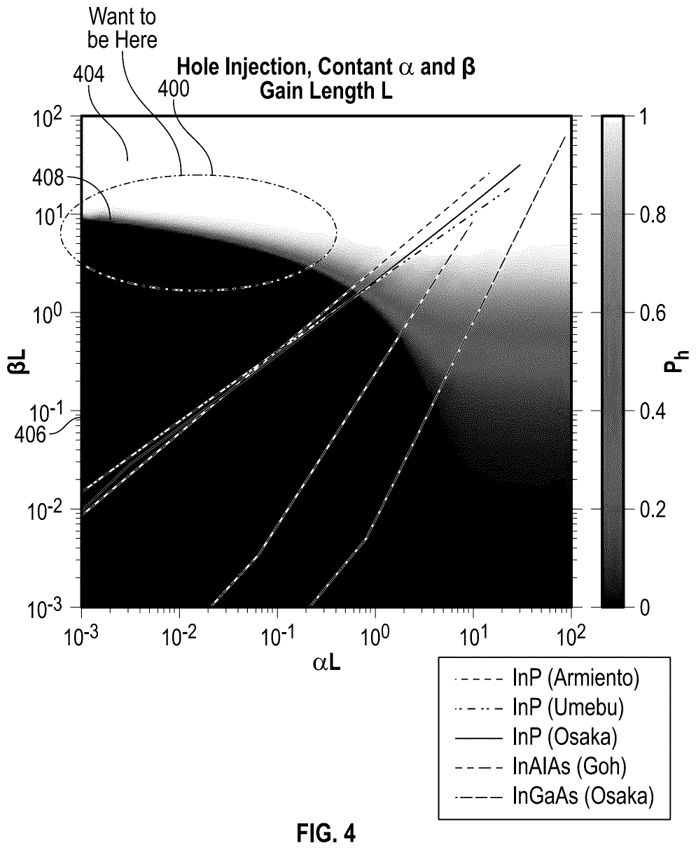

PDE is determined as Internal Quantum Efficiency (IQE)×Probability of Avalanche (PA)(PDE=IQE×PA). The techniques described herein leverage a compositionally graded gain region to increase the PA so as to increase the PDE. FIG. 4 shows, as an example, a target area to be with a constant α and β to increase PDE. As an example, a PA is 100% in region 404, a PA is 0% in region 406, and a PA transitions from 0% to 100% in region 408. As shown in FIG. 4, a series of αL−βL lines running from the lower left to the upper right are the measured αL and βL of some materials that may be used in GmAPDs. The closer a point is to the upper right end in each line, the higher the applied voltage is. A material with a αL−βL line going through region 400 where the transition (region 408) is narrowest may require the smallest overbias voltage and result in the lowest dark current. Accordingly, region 400 may be a preferred operation region for a material when a/b<1. While FIG. 4 illustrates a preferred operation point when a/b<1, a similar type of graph with a similar preferred operation region applies when a/b>1.

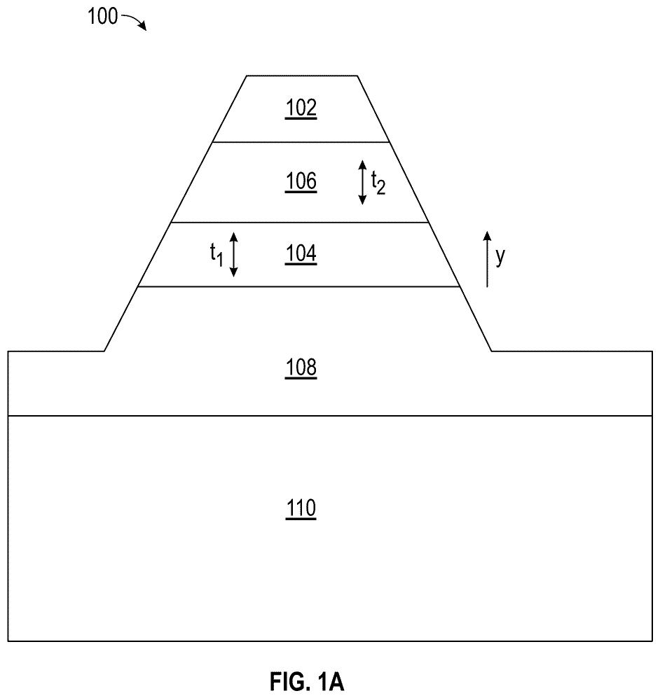

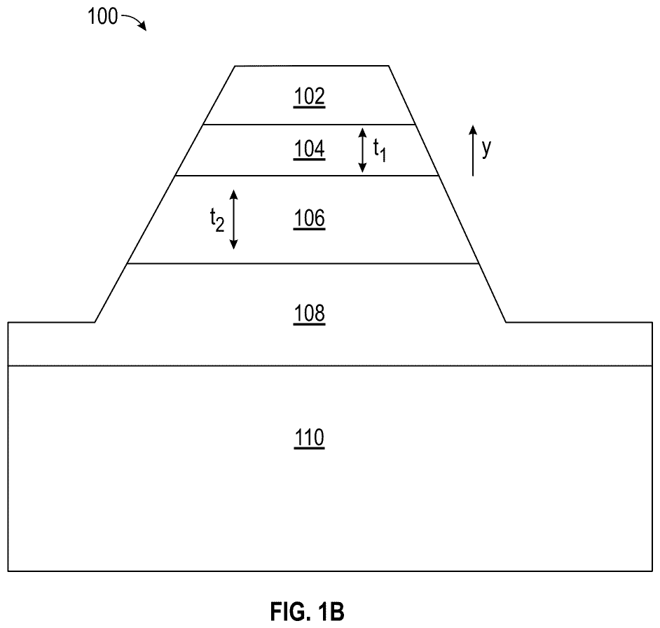

FIGS. 1A-1B show examples of a photodiode 100 in accordance with techniques described herein. FIGS. 1A-1B show examples of photodiode 100 having a mesa structure. In some examples, photodiode 100 may be an avalanche photodiode or a GmAPD. A GmAPD may be operated slightly above a breakdown threshold voltage, where a single electron-hole pair (generated by absorption of a photon or by a thermal fluctuation) may trigger a strong avalanche. In the case of such an event, an electronic quenching circuit reduces the voltage at the photodiode below the threshold voltage for a short time, so that the avalanche is stopped and the detector is ready for detection of further photons after some recovery time.

Photodiode 100 may include one or more of a first contact region 102, a first semiconductor alloy 104, a second semiconductor alloy 106, a second contact region 108, and a semiconductor substrate 110. In some examples, the layers 102, 104, 106, 108 of photodiode 100 have tapered sidewalls to form a tapered mesa structure. In some examples, photodiode 100 may be an avalanche photodiode (APD). In some examples, photodiode 100 may be a GmAPD.

In some examples, semiconductor substrate 110 may be an Indium Phosphide (InP) substrate. In some examples, first contact region 102 may be a semiconductor layer, such as a n⁺-InP contact layer. In some examples, second contact region 108 may be a semiconductor layer, such as a p⁺-InP contact layer.

First semiconductor alloy 104 forms a compositionally graded gain region having a non-homogenous composition and/or structure in the y-direction, as shown in FIGS. 1A-1B.

In an example as shown in FIG. 1A, first semiconductor alloy 104 may be an n-type layer, such as an n⁻-InP layer and second semiconductor alloy 106 may be a n⁻ Indium Gallium Arsenide (InGaAs) layer, or a n⁻ Indium Gallium Arsenic Phosphide (InGaAsP) layer. In some examples, photodiode 100 of FIG. 1A may be configured for hole injection.

In an example as shown in FIG. 1B, first semiconductor alloy 104 may be a p-type layer, such as a p⁻-InP layer and second semiconductor alloy 106 may be a p⁻ InGaAs layer, or a p⁻ InGaAsP layer. In some examples, photodiode 100 of FIG. 1B may be configured for electron injection.

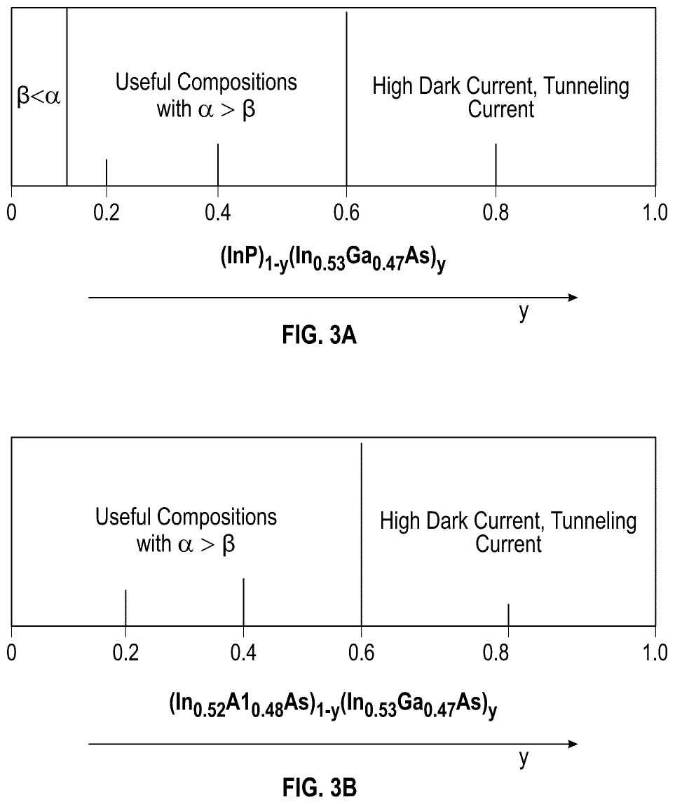

In some examples, other alloys may be used for first semiconductor alloy 104 and/or second semiconductor alloy 106, such as Indium Gallium Aluminum Arsenide (InGaAlAs). In some examples, as shown in FIG. 3A, first semiconductor alloy 104 may be (InP)_{1-y}(In_{0.53}Ga_{0.47}As)_{y} with y ranging between 0.1 to 0.6. In some examples, as shown in

FIG. 3B, first semiconductor alloy 104 may be (In_{0.52}Al_{0.48}As)_{1-y}(In_{0.53}Ga_{0.47}As)_{y} with y ranging between 0 to 0.6. As shown in FIGS. 1A-1B. A “y” direction is in a direction from semiconductor substrate 110 toward first contact region 102, “0” in the y-direction may correspond to the lower portion of first semiconductor alloy 104 while “1” in the y-direction may correspond to the upper portion of first semiconductor alloy 104. As y increases, the proportions of the metals within the alloy decrease and increase, respectively. However, it is not required that y constitute the entire height of first semiconductor alloy 104 as shown in FIGS. 1A-1B. That is, in some cases, the height of the compositionally graded portion of first semiconductor alloy 104 may be less than the height of first semiconductor alloy 104. The compositionally graded portion of first semiconductor alloy 104 may begin and end at any two heights within first semiconductor alloy 104.

It may be beneficial to have a graded gain region with the one or more of the following properties: (1) its composition is varied continuously to give conduction band and valence band quasi-fields that cause electrons and holes to drift in the same direction; (2) its composition remains lattice-matched to the substrate for the full range of its compositional variation so that crystal defects do not form; and (3) the bandgap energy for the full range of its compositional variation is sufficiently large that band-to-band tunneling currents are negligibly small. The choice of graded gain regions can be systematically searched by considering ternary alloys lattice-matched to the binary substrate. For example, a graded gain region lattice-matched to InP is an admixture of the lattice-matched ternaries In_{0.52}Al_{0.48}As and In_{0.53}Ga_{0.47}As. Another graded gain regions lattice-matched to InP is an admixture of the binary InP and of the lattice-matched ternary In_{0.53}Ga_{0.47}As. A graded gain regions lattice-matched to GaSb is an admixture of the binary GaSb and the lattice-matched ternary AlAs_{0.08}Sb_{0.92}. Not all pairs lead to a practical layer; some may be thermodynamically unstable or have too small of a bandgap.

FIGS. 3A and 3B are examples of how first semiconductor alloy 104 may form a compositionally graded region, but first semiconductor alloy 104 may form a compositionally graded region in other fashions as well.

In some examples, first semiconductor alloy 104 may be composed of two or more lattice-matched semiconductor alloys and/or second semiconductor alloy 106 may be composed of two or more lattice-matched semiconductor alloys.

In some examples, first semiconductor alloy 104 may have a thickness “t₁” less than a thickness “t₂” of second semiconductor alloy 106. In some examples, thickness t₁ of first semiconductor alloy 104 is less than thickness t₂ of second semiconductor alloy 106. In some examples, thickness t₁ of first semiconductor alloy 104 is greater than thickness t₂ of second semiconductor alloy 106. In some examples, as shown in FIG. 1A, first semiconductor alloy 104 may be positioned between second semiconductor alloy 106 and semiconductor substrate 110. In some examples, as shown in FIG. 1B, second semiconductor alloy 106 may positioned between first semiconductor alloy 104 and semiconductor substrate 110.

In some examples, first semiconductor alloy 104 forms a compositionally graded gain region configured to form a conduction band having free electrons, a valence band having free holes, and a bandgap between the valence band and the conduction band that varies in size across the graded gain region, and second semiconductor alloy 106 forms an absorber region.

In some examples, first semiconductor alloy 104 forms a compositionally graded gain region with a spatial grading in the bandgap so that the gain region has a larger bandgap at one end and a smaller bandgap in the other end. If the smaller bandgap lies within the larger bandgap, that is if the conduction band energy decreases going from the large bandgap terminus to the small bandgap terminus while the valence band energy increases, the tilted bands may produce a quasi-electric field in opposite directions for electrons and holes.

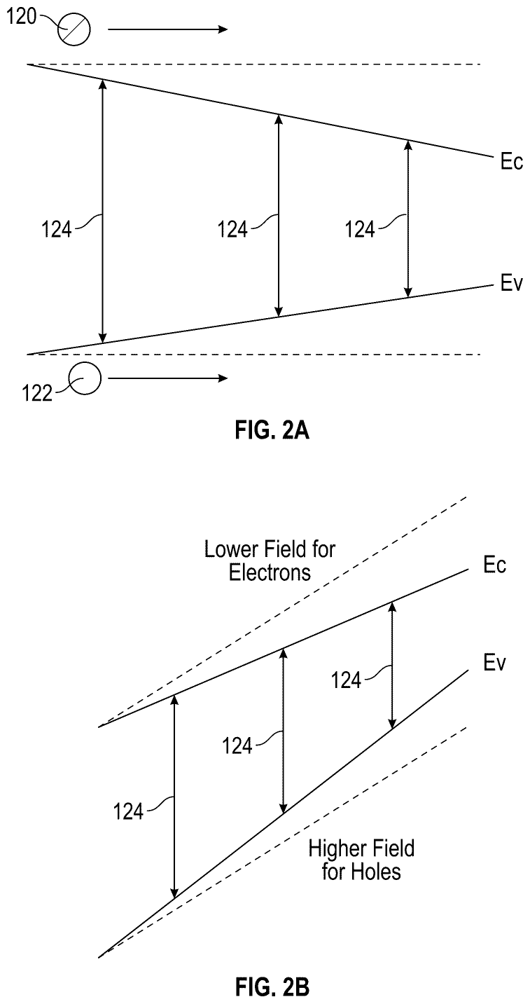

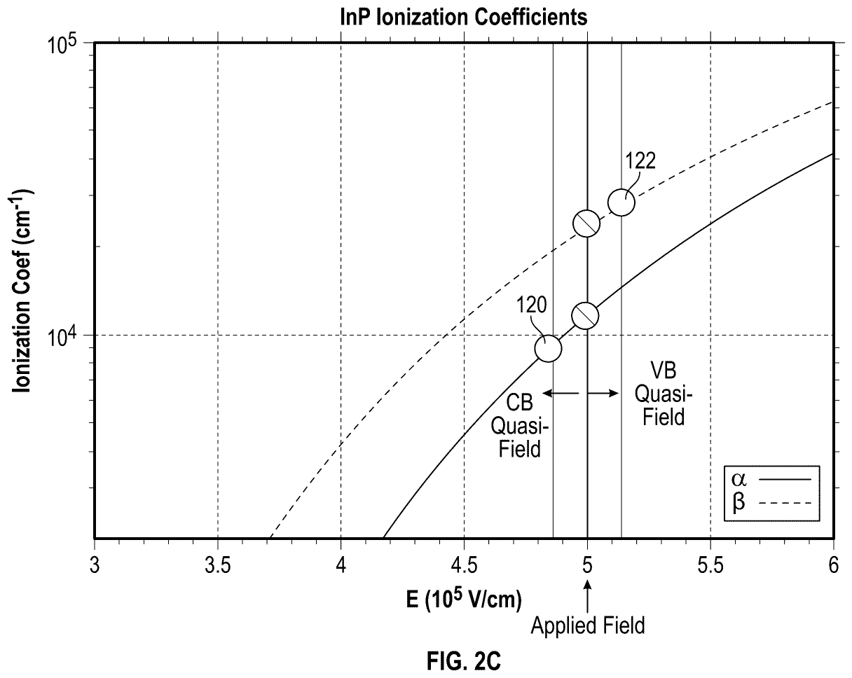

FIG. 2A shows an example of conduction band Ec having a free electron 120 and valence band Ev having a free hole 122. The conduction band Ec and valence band Ev are separated by a bandgap 124. Free electrons reside in the conduction band Ec and free holes in the valence band Ev. The conduction band Ec and the valence band Ev are separated by the bandgap of width 124 where there are no allowed electron or hole states. A vertical distance between the electron's instantaneous position and the conduction band Ec is the instantaneous kinetic energy of the electron. Once the kinetic energy of the electron exceeds the bandgap energy, it has enough energy to create an electron-hole pair by impact ionization. When the electron does impact ionize, most of the kinetic energy goes into creating an electron-hole pair and results in two electrons and one hole with very little kinetic energy. Electron-initiated impact ionization is characterized by a coefficient α, the average number of electron-initiated impact ionization per centimeter. A similar chain of events may happen in the valence band Ev with a hole accelerating to create an electron-hole pair. In this case, there are two holes and one electron after the hole-initiated impact ionization. This process is characterized by the hole-initiated impact ionization coefficient β.

Bandgap 124 may vary in size across the graded gain region formed by the first semiconductor alloy 104, such as varying in distance. FIG. 2A shows an example of first semiconductor alloy 104 forming a compositionally graded gain region with photodiode 100 not being electrically biased to conduct electrical current, while FIG. 2B shows an example of first semiconductor alloy 104 forming a compositionally graded gain region with photodiode 100 being electrically biased to conduct electrical current.

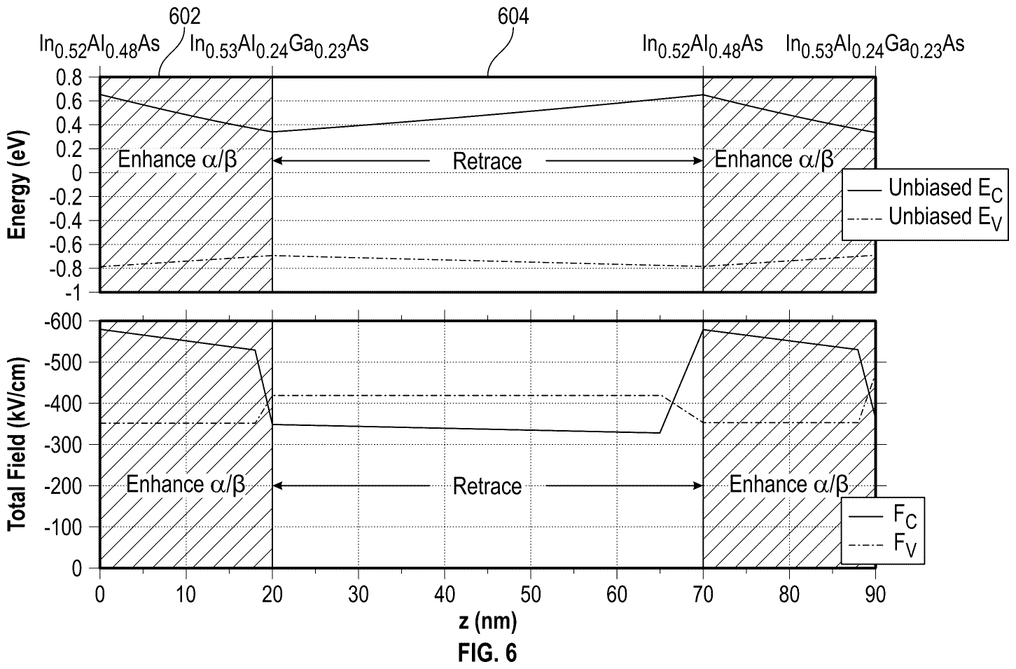

To create the largest quasifields, a composition gradient should be as large as possible. FIG. 6 shows an example of a first semiconductor alloy 104 forming compositionally graded gain regions. In some examples, in first semiconductor alloy 104, a length of a gain region with a single enhancement region with grading may be insufficient to achieve avalanche breakdown, so several enhancement regions may be cascaded with retrace regions to obtain sufficient gain. In some examples, first semiconductor alloy 104 may include one or more enhancement regions and one or more retrace regions. The enhancement regions and retrace regions may be cascaded with respect to each other in the first semiconductor alloy 104. In some examples, enhancement regions cascading with retrace regions may be a respective enhancement region alternating with a respective retrace region in the first semiconductor alloy 104. FIG. 6 shows a non-limiting example of example compositions of respective enhancement regions and retrace regions. For example, as shown in FIG. 6, enhancement region 602 may be comprised of In_{0.52}Al_{0.48}As and retrace region 604 may be comprised of In_{0.53}Al_{0.24}Ga_{0.23}As. However, enhancement regions and/or retrace regions may have other compositions as well. In some examples, each enhancement region may be comprised of a similar composition. In some examples, some enhancement regions may be comprised of a different composition than other enhancement regions. In some examples, each retrace region may be comprised of a similar composition. In some examples, some retrace regions may be comprised of a different composition than other enhancement retrace regions.

As shown in FIGS. 1A-1B, a “y” direction is in a direction from semiconductor substrate 110 toward first contact region 102, “0” in the y-direction may correspond to the lower portion of first semiconductor alloy 104 while “1” in the y-direction may correspond to the upper portion of first semiconductor alloy 104. In some examples, enhancement regions cascading with retract region may be a respective enhancement region alternating with a respective retrace region from “0” to “1” along the y direction of the first semiconductor alloy 104. In some examples, an enhancement region may be configured to decrease a size of the bandgap from “0” to “1” along the y direction. A retrace region may be configured to increase a size of the bandgap from “0” to “1” along the y direction. In some examples, the rate of decrease in size of bandgap in an enhancement region may be greater than the rate of increase in size of bandgap in a retrace region. In some examples, a rate of increase in size of bandgap in a retrace region may be 2-3 times slower than a rate of decrease in size of bandgap in an enhancement. The retrace region(s) may be configured to increase a size of bandgap at a speed that will not cancel the enhancement of the enhancement region but also not dilute the enhancement.

In some examples, the graded gain region of first semiconductor alloy 104 may be compositionally graded to generate a bandgap 124 that periodically varies in size across the graded gain region. For example, the graded gain region of first semiconductor alloy 104 may be compositionally graded in a sawtooth fashion to generate a bandgap 124 that periodically varies in size across the graded gain region in a sawtooth fashion. The bandgap 124 may decrease in size from one end of the graded gain region to an other end of the graded gain region, such as bandgap 124 gradually decreasing in size, such as a moving average of size, from one end of the graded gain region to an other end, while periodically varying in size.

Two parameters used to characterize an APD are the electron-initiated impact ionization coefficient α and the hole-initiated impact-ionization coefficient β. First semiconductor alloy 104 forming a compositionally graded gain region may create a quasi-field F_{quasi} that may have a different sign for electrons and holes. A quasi-field, such as one having a different sign for electrons and holes, may add to the applied field Fₐₚₚₗ for one carrier while subtracting to the field for the other carrier as an ionization ratio α(Fₐₚₚₗ)/β(Fₐₚₚₗ) may be decreased to α(Fₐₚₚₗ−F_{quasi})/β(Fₐₚₚₗ+F_{quasi}).

FIG. 2C shows an example an effect the generation of a quasi-field by a compositionally graded gain region, such as one having a different sign for electrons and holes, may have to an applied field of a respective electron 120 and/or hole 122.

Accordingly, first semiconductor alloy 104 forming a compositionally graded gain region may give rise to quasi-electric fields that add to the applied field for one carrier and that subtracts from the applied field for the other. With the quasi-fields, it is possible to enhance the difference between the electron-initiated ionization rate and the hole-initiated ionization rate over the difference with only an applied field and thereby increase the avalanche probability.

In some examples, the quasi-field may add to the applied field for the carrier with a higher ionization rate and will subtract from the applied field for the carrier with a lower ionization rate based on grading direction. Thus, a bandgap may be configured to generate a quasi-field to change the α/β ratio in a direction needed to lower the bias to obtain a target value of PDE. With the strong dependence of α and β with an electric field, the modest quasi-fields may give a relatively large change in α/β.

In some examples, the grading of the gain region of first semiconductor alloy 104 may be achieved using epitaxial growth techniques. In some examples, the grading of the gain region of first semiconductor alloy 104 may be achieved using a series of steps consisting of slightly different, constant bandgap materials. For example, bandgap 124 may be configured to add the generated quasi-field to the valence band and subtract the generated quasi-field from the conduction band. As another example, bandgap 124 may be configured to subtract the generated quasi-field from the valence band and add the generated quasi-field to the conduction band.

First semiconductor alloy 104 forming a compositionally graded gain region to generate a quasi-field to be added to the valence band and subtracted from the conduction band may enhance the difference between the electron-initiated ionization rate and the hole-initiated ionization rate to thereby increase the avalanche probability, which increases the PDE.

A photodiode having a higher PDE may lead to higher sensitivity. For a LIDAR system, this means that it can detect longer distances at the same laser power or detect to the same distance at lower laser power. For low light level imaging, higher sensitivity means shorter acquisition time for the same quality images or higher quality images at the same acquisition time. For chemical and biological sensing and analysis, this means smaller quantities of the analyte can be detected. The performance improvement with increasing the PDE of a photodiode, such as a GmAPD, may seem modest, but it may enable large tradeoffs to be made. For example, doubling the PDE of the GmAPDs in a LIDAR system may not change the size, weight, or power requirement but doubling the power of the laser to achieve the same improvement in performance will nearly double the size, weight, and power requirement.

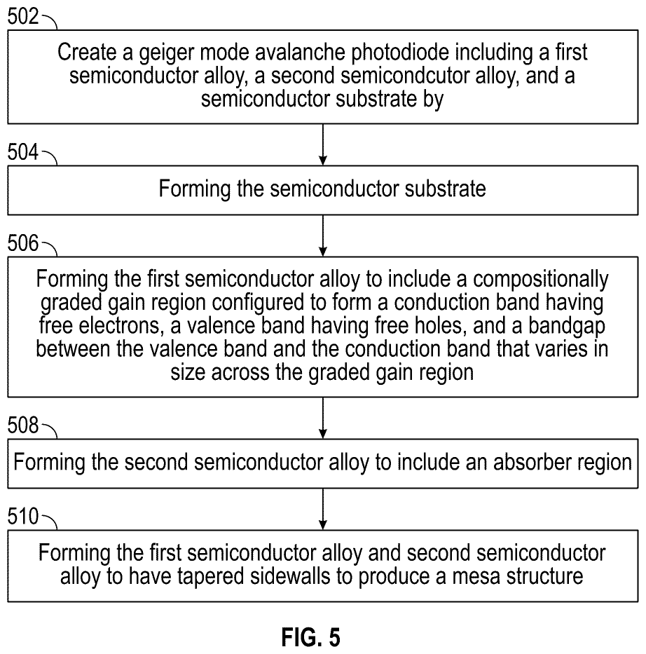

FIG. 5 is a flow diagram illustrating an example method for creating a photodiode configured to have increased avalanche probability, in accordance with one or more techniques of this disclosure. As an example, a method may include creating an avalanche photodiode including a first semiconductor alloy, a second semiconductor alloy, and a semiconductor substrate (502) by: forming the semiconductor substrate 110 (504); forming the first semiconductor alloy 104 to include a compositionally graded gain region configured to form a conduction band having free electrons, a valence band having free holes, and a bandgap between the valence band and the conduction band that varies in size across the graded gain region (506); forming the second semiconductor alloy 106 to include an absorber region (508). In some optional examples, the method for creating the avalanche photodiode may further include forming each of the first semiconductor alloy 104 and the second semiconductor alloy 106 to have tapered sidewalls to produce a mesa structure (510).

An avalanche photodiode 100, in one or more of the examples as described above, may detect a photon detection by receiving a photon incident to the second semiconductor alloy 106. In response, avalanche photodiode 100 may generate a gain by amplifying a current produced by the photon across the compositionally graded gain region of the first semiconductor alloy 104. In response, avalanche photodiode 100 may output an electrical signal based on the generated gain.

The foregoing system and embodiments thereof have been provided in sufficient detail, but it may be not the intention of the applicant(s) for the disclosed system and embodiments provided herein to be limiting. Additional adaptations and/or modifications are possible, and, in broader aspects, these adaptations and/or modifications are also encompassed. Accordingly, departures may be made from the foregoing system and embodiments without departing from the spirit of the system.

1. A Geiger mode avalanche photodiode comprising:
a first semiconductor alloy forming a compositionally graded gain region configured to form a conduction band having free electrons, a valence band having free holes, and a bandgap between the valence band and the conduction band that varies in size across the graded gain region;
a second semiconductor alloy forming an absorber region; and
a semiconductor substrate.

2. The Geiger mode avalanche photodiode as recited in claim 1, wherein the bandgap periodically varies in size across the graded gain region.

3. The Geiger mode avalanche photodiode as recited in claim 1, wherein the bandgap decreases in size from one end of the graded gain region to an other end of the graded gain region.

4. The Geiger mode avalanche photodiode as recited in claim 1, wherein the bandgap is configured to generate a quasi-field having a different sign for the free electrons than the free holes.

5. The Geiger mode avalanche photodiode as recited in claim 1, wherein the first semiconductor alloy and second semiconductor alloy are positioned in accordance with one of 1) the second semiconductor alloy being positioned between the first semiconductor alloy and the semiconductor substrate or 2) the first semiconductor alloy being positioned between the second semiconductor alloy and the semiconductor substrate.

6. The Geiger mode avalanche photodiode as recited in claim 1, wherein the first semiconductor alloy is composed of two or more lattice-matched semiconductor alloys.

7. The Geiger mode avalanche photodiode as recited in claim 1, wherein the avalanche photodiode has a mesa structure.

8. The Geiger mode avalanche photodiode as recited in claim 1, wherein the first semiconductor alloy and second semiconductor alloy are lattice matched to the semiconductor substrate.

9. The Geiger mode avalanche photodiode as recited in claim 1, wherein each of the first semiconductor alloy and the second semiconductor alloy have tapered sidewalls to produce a mesa structure.

10. The Geiger mode avalanche photodiode as recited in claim 1, wherein the first semiconductor alloy includes:
one or more enhancement regions; and
one or more retrace regions,
wherein the one or more enhancement regions and the one or more retrace regions are configured to be cascaded with respect to each other in the first semiconductor alloy.

11. A method comprising:
creating a Geiger mode avalanche photodiode by:
forming a semiconductor substrate;
forming a first semiconductor alloy to include a compositionally graded gain region configured to form a conduction band having free electrons, a valence band having free holes, and a bandgap between the valence band and the conduction band that varies in size across the graded gain region; and
forming a second semiconductor alloy to include an absorber region.

12. The method as recited in claim 11, wherein forming the first semiconductor alloy comprising forming the bandgap to periodically vary in size across the graded gain region.

13. The method as recited in claim 11, wherein forming the first semiconductor alloy comprising forming the bandgap to decrease in size from one end of the graded gain region to an other end of the graded gain region.

14. The method as recited in claim 11, wherein forming the first semiconductor alloy comprising forming the bandgap to generate a quasi-field having a different sign for the free electrons than the free holes.

15. The method as recited in claim 11, wherein forming the first semiconductor alloy and forming the second semiconductor alloy comprising one of 1) forming the second semiconductor alloy to be positioned between the first semiconductor alloy and the semiconductor substrate, or 2) forming the first semiconductor alloy to be positioned between the second semiconductor alloy and the semiconductor substrate.

16. The method as recited in claim 11, wherein forming the first semiconductor alloy comprising forming the first semiconductor alloy of two or more lattice-matched semiconductor alloys.

17. The method as recited in claim 11, wherein creating the avalanche photodiode comprising forming the first semiconductor alloy and the second semiconductor alloy to have a mesa structure.

18. The method as recited in claim 11, wherein forming the first semiconductor alloy comprising forming the first semiconductor alloy and second semiconductor alloy as lattice matched to the semiconductor substrate.

19. The method as recited in claim 11, wherein forming the first semiconductor alloy comprising forming the first semiconductor alloy having one or more enhancement regions and one or more retrace regions that cascade with respect to each other.

20. A photon detection method, comprising:
receiving, by the Geiger mode avalanche photodiode recited in claim 1, a photon incident to the second semiconductor alloy;
generating, by the first semiconductor alloy, a gain by amplifying a current, produced by the photon, across the compositionally graded gain region; and
outputting, by the avalanche photodiode, an electrical signal based on the gain.
